(19) United States
(12) Patent Application Publication
(10) Pub. No.: US 2017/0278699 A1
(43) Pub. Date: Sep. 28, 2017

(54) CONTROL DEVICE, SUBSTRATE PROCESSING SYSTEM, SUBSTRATE PROCESSING METHOD, AND PROGRAM

(71) Applicant: Tokyo Electron Limited, Tokyo (JP)

(72) Inventors: Takahito Kasai, Iwate (JP); Yuichi Takenaga, Iwate (JP); Kazumi Kubo, Iwate (JP)

(21) Appl. No.: 15/466,136

(22) Filed: Mar. 22, 2017

(30) Foreign Application Priority Data
Mar. 24, 2016 (JP) 2016-059725

(51) Int. Cl. H01L 21/02; C23C 16/34; C23C 16/52; H01L 21/66; C23C 16/455

(52) U.S. Cl. CPC H01L 21/0228; H01L 21/0217; H01L 22/12; C23C 16/45544; C23C 16/52; C23C 16/45553; C23C 16/345

(57) ABSTRACT

Disclosed is a control device that controls an operation of a substrate processing apparatus. The control device includes a recipe memory unit that stores a film formation condition according to a type of the film, a model memory unit that stores a process model that represents an effect of the film formation condition on a property of the film, a log memory unit that stores an actual measurement value of the film formation condition during film formation, and a controller that calculates a film formation condition that satisfies a target property of the film based on a measured result of the property of the film formed based on the film formation condition stored in the recipe memory unit, the process model stored in the model memory unit, and the actual measurement value of the film formation condition stored in the log memory unit.

### CROSS-REFERENCE TO RELATED APPLICATIONS

This application is based on and claims priority from Japanese Patent Application No. 2016-059725, filed on Mar. 24, 2016, with the Japan Patent Office, the disclosure of which is incorporated herein in its entirety by reference.

### TECHNICAL FIELD

The present disclosure relates to a control device, a substrate processing system, a substrate processing method, and a program.

### BACKGROUND

In manufacturing a semiconductor device, when a film having a predetermined property is formed on a substrate, such as, for example, a semiconductor wafer (wafer), an optimum film formation condition under which the film having the predetermined property is acquired is calculated in advance, and film formation is performed on the substrate using the calculated optimum film formation condition. When the optimum film formation condition is calculated, a knowledge or experience related to a semiconductor manufacturing apparatus or a semiconductor process is required, and the optimum film formation condition may not be easily calculated in some cases.

Conventionally, as a system that calculates an optimum film formation condition, a thermal processing system is known, in which a controller calculates an optimum temperature, which is close to a target film thickness, merely by an operator's inputting of the target film thickness (see, e.g., Japanese Patent Laid-Open Publication No. 2013-207256). In this system, the controller calculates the optimum film formation condition with reference to film thickness data measured using a film thickness gauge.

### SUMMARY

A control device according to one aspect of the present disclosure is configured to control an operation of a substrate processing apparatus that forms a film on a substrate by atomic layer deposition, and includes a recipe memory unit configured to store a film formation condition according to a type of the film, a model memory unit configured to store a process model that represents an effect of the film formation condition on a property of the film, a log memory unit configured to store an actual measurement value of the film formation condition during film formation, and a controller configured to calculate a film formation condition that satisfies a target property of the film based on a measured result of the property of the film formed based on the film formation condition stored in the recipe memory unit, the process model stored in the model memory unit, and the actual measurement value of the film formation condition stored in the log memory unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating an exemplary configuration of a substrate processing apparatus according to an exemplary embodiment.

FIG. 2 is a schematic view illustrating an exemplary configuration of a control device according to an exemplary embodiment.

FIG. 3 is a flowchart illustrating an exemplary operation of the control device according to the exemplary embodiment.

FIG. 4 is a view illustrating the set temperatures of a heater in each zone before and after an adjustment processing.

FIG. 5 is a view illustrating the numbers of cycles of ALD before and after an adjustment processing.

FIG. 6 is a view illustrating film thicknesses of an SiN film in each zone before and after an adjustment processing.

FIG. 7 is a view illustrating an inter-plane uniformity in film thickness of a SiN film before and after an adjustment processing.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

When a film having a predetermined property is formed on a substrate by atomic layer deposition (ALD), it is difficult to calculate an optimum film formation condition by adjusting a plurality of parameters (e.g., temperature, gas flow rate, pressure, and number of cycles).

Thus, in one aspect, the present disclosure provides a control device, which may allow an operator to easily calculate an optimum film formation condition under which a film is formed on a substrate by atomic layer deposition even if the operator has little knowledge or experience related to a semiconductor manufacturing apparatus or a semiconductor process.

According to an aspect of the present disclosure, there is provided a control device for controlling an operation of a substrate processing apparatus that forms a film on a substrate by atomic layer deposition. The control device includes: a recipe memory unit configured to store a film formation condition according to a type of the film; a model memory unit configured to store a process model that represents an effect of the film formation condition on a property of the film; a log memory unit configured to store an actual measurement value of the film formation condition during film formation; and a controller configured to calculate a film formation condition that satisfies a target property of the film based on a measured result of the property of the film formed based on the film formation condition stored in the recipe memory unit, the process model stored in the model memory unit, and the actual measurement value of the film formation condition stored in the log memory unit.

In the control device, the film formation condition includes a temperature of the substrate, the model memory unit further stores a thermal model that represents a relationship between the temperature of the substrate and a set temperature of a heater that heats the substrate, and the controller determines the set temperature of the heater based on the thermal model stored in the model memory unit so that the temperature of the substrate becomes a temperature calculated by the process model.

In the control device, the controller adjusts the film formation condition based on the actual measurement value of the film formation condition stored in the log memory unit such that power of the heater is not saturated.

In the control device, wherein the controller calculates the film formation condition that satisfies the target property of the film using an optimization algorithm.

In the control device, the property of the film is a film thickness.

According to another aspect of the present disclosure, there is provided a substrate processing system that includes a substrate processing apparatus that form a film on a substrate by atomic layer deposition, and a control device configured to control an operation of the substrate processing apparatus. The control device includes: a recipe memory unit configured to store a film formation condition according to a type of the film; a model memory unit configured to store a process model that represents an effect of the film formation condition on a property of the film; a log memory unit configured to store an actual measurement value of the film formation condition during film formation; and a controller configured to calculate a film formation condition that satisfies a target property of the film based on a measured result of the property of the film formed based on the film formation condition stored in the recipe memory unit, the process model stored in the model memory unit, and the actual measurement value of the film formation condition stored in the log memory unit.

In the substrate processing system, the substrate processing apparatus includes: a substrate holding mechanism configured to hold a plurality of substrates at predetermined intervals in a vertical direction; a processing container configured to accommodate the substrate holding mechanism therein; and a gas supply unit configured to supply a first processing gas and a second processing gas, which reacts with the first processing gas, into the processing container.

In the substrate processing system, the first processing gas is dichlorosilane gas, and the second processing gas is ammonia gas.

According to another aspect, there is provided a substrate processing method that includes: forming a film on a substrate using a predetermined film formation condition by atomic layer deposition; measuring a property of the film formed in the film formation process; and calculating a film formation condition that satisfies a target property of the film based on a measured result of the property of the film formed based on a measured result of the property of the film measured in the measurement process, a process model that represents an effect of the film formation condition on the property of the film, and an actual measurement value of the film formation condition during film formation.

According to yet another aspect of the present disclosure, there is provided a non-transitory computer-readable storage medium which stores a program that, when executed, causes a computer to perform the above-described substrate processing method.

According to the control device disclosed herein, an operator may easily calculate an optimum film formation condition under which a film is formed on a substrate by atomic layer deposition even if the operator has little knowledge or experience related to a semiconductor manufacturing apparatus or a semiconductor process.

Hereinafter, an exemplary embodiment for carrying out the present disclosure will be described with reference to the drawings. In addition, in this specification and drawings, substantially the same configurations will be given the same reference numerals, and redundant descriptions will be omitted.

(Substrate Processing Apparatus)

A substrate processing apparatus of the present exemplary embodiment will be described. The substrate processing apparatus of the present exemplary embodiment is a batch-type apparatus in which a substrate holding mechanism may be accommodated in a processing container so as to hold therein a plurality of semiconductor wafers (hereinafter, referred to as “wafers”) as exemplary substrates at predetermined intervals in the vertical direction, and a film may be formed on the wafers at the same time by atomic layer deposition (ALD).

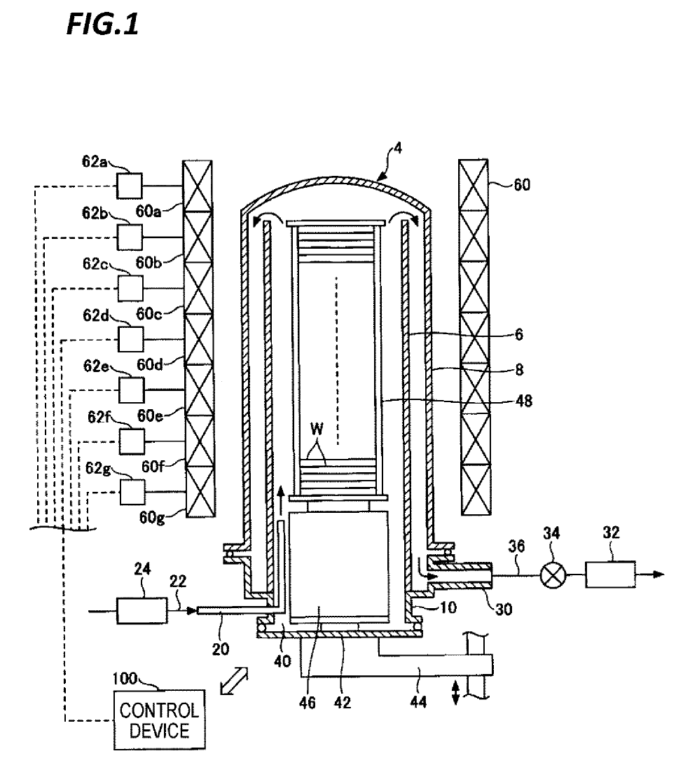

Hereinafter, a description will be made based on FIG. 1. FIG. 1 is a schematic view illustrating an exemplary configuration of the substrate processing apparatus according to the present exemplary embodiment.

As illustrated in FIG. 1, the substrate processing apparatus includes a processing container 4 having a substantially cylindrical shape, the longitudinal direction of which is the vertical direction. The processing container 4 has a double pipe structure including a cylindrical inner cylinder 6, and a ceilinged outer cylinder 8 concentrically disposed outside the inner cylinder 6. The inner cylinder 6 and the outer cylinder 8 are formed of, for example, a heat-resistant material such as quartz.

The inner cylinder 6 and the outer cylinder 8 are held at the lower ends thereof by a manifold 10, which is formed of, for example, stainless steel. The manifold 10 is fixed to, for example, a base plate (not illustrated). In addition, because the manifold 10 defines an inner space having a substantially cylindrical shape along with the inner cylinder 6 and the outer cylinder 8, it is assumed that the manifold 10 forms a portion of the processing container 4. That is, the processing container 4 includes the inner cylinder 6 and the outer cylinder 8, which are formed of, for example, a heat-resistant material such as quartz, and the manifold 10, which is formed of, for example, stainless steel, and the manifold 10 is provided below the side surface of the processing container 4 so as to hold the inner cylinder 6 and the outer cylinder 8 from the lower side.

The manifold 10 includes a gas introduction part 20 configured to introduce various gases such as, for example, a processing gas such as a film formation gas that is used in a film formation processing, and a purge gas used in a purge processing, into the processing container 4. Although FIG. 1 illustrates a form in which one gas introduction part 20 is provided, the present disclosure is not limited thereto, and a plurality of gas introduction parts 20 may be provided according to, for example, gas species to be used.

The type of the film formation gas is not particularly limited, and may be appropriately selected according to, for example, the type of a film to be formed. For example, when a silicon nitride film (SiN film) is formed on a wafer W by ALD, dichlorosilane gas (DCS gas) and ammonia gas (NH₃ gas) may be used. At this time, by repeatedly and alternately supplying the DCS gas and the NH₃ gas by a predetermined number of cycles into the processing container 4, the SiN film may be formed on the wafer W by a reaction product of the DCS gas and the NH₃ gas. In addition, the DCS gas is an exemplary first processing gas, and the NH₃ gas is an exemplary second processing gas.

The type of the purge gas is not particularly limited, and for example, may use an inert gas such as, for example, nitrogen (N₂) gas.

The gas introduction part 20 is connected to an introduction pipe 22 that is configured to introduce various gases into the processing container 4. In addition, the introduction pipe 22 is provided with, for example, a flow rate adjustment unit 24, such as a mass-flow controller, or a valve (not illustrated), so as to adjust a gas flow rate. The gas introduction part 20, the introduction pipe 22, the flow rate adjustment unit 24, and the valve constitute an exemplary gas supply device.

In addition, the manifold 10 includes a gas exhaust part 30 to evacuate the inside of the processing container 4. The gas exhaust part 30 is connected to an exhaust pipe 36, which includes, for example, a vacuum pump 32 capable of controlling the reduction of pressure within the processing container 4 and an opening variable valve 34.

The manifold 10 includes a furnace opening 40 formed in the lower end thereof, and the furnace opening 40 is provided with a cover 42, which has a disc shape and is formed of, for example, stainless steel. The cover 42 is provided to be movable up and down by, for example, an elevating mechanism 44, which functions as a boat elevator, and is configured to hermetically seal the furnace opening 40.

A heat insulating cylinder 46, which is formed of, for example, quartz, is installed above the cover 42. A wafer boat 48, which is formed of, for example, quartz, is disposed above the heat insulation cylinder 46 to hold, for example, about 50 to 175 wafers W in the horizontal state at predetermined intervals in multiple stages.

The wafer boat 48 is loaded (carried) into the processing container 4 by moving up the cover 42 using the elevating mechanism 44, and various film formation processings are performed on the wafers W held in the wafer boat 48. After the various film formation processings are performed, the wafer boat 48 is unloaded (carried out) from the processing container 4 to a loading area therebelow by moving down the cover 42 using the elevating mechanism 44.

On the outer circumferential side of the processing container 4, for example, a heater 60 having a cylindrical shape is provided to heat the processing container 4 to a predetermined temperature in a controlled manner.

The heater 60 is divided into a plurality of zones so that heaters 60a to 60g are provided from the top side to the bottom side in the vertical direction. The heaters 60a to 60g are configured such that the calorific values thereof may be independently controlled by power controllers 62a to 62g respectively. In addition, the inner wall of the inner cylinder 6 and/or the outer wall of the outer cylinder 8 are provided with temperature sensors (not illustrated) to correspond to the respective heaters 60a to 60g. Hereinafter, the zones in which the heaters 60a to 60g are provided are referred to as zone 1 to zone 7. In addition, although FIG. 1 illustrates a form in which the heater 60 is divided into seven zones, the present disclosure is not limited thereto, and the heater 60 may be divided into, for example, six or less zones or eight or more zones from the top side to the bottom side in the vertical direction. In addition, the heater 60 may not be divided into a plurality of zones.

The wafers W disposed in the wafer boat 48 constitute a single batch, and various film formation processings are performed on a per batch basis. In addition, at least one wafer W disposed in the wafer boat 48 may be a monitor wafer. In addition, the monitor wafer may be disposed to correspond to each of the divided heaters 60a to 60g.

In addition, the substrate processing apparatus of the present embodiment includes a control device 100, such as, for example, a computer to control an operation of the entire apparatus. The control device 100 is connected to a host computer by, for example, a wireless or wired communication device, and the substrate processing apparatus constitutes a substrate processing system.

(Control Device)

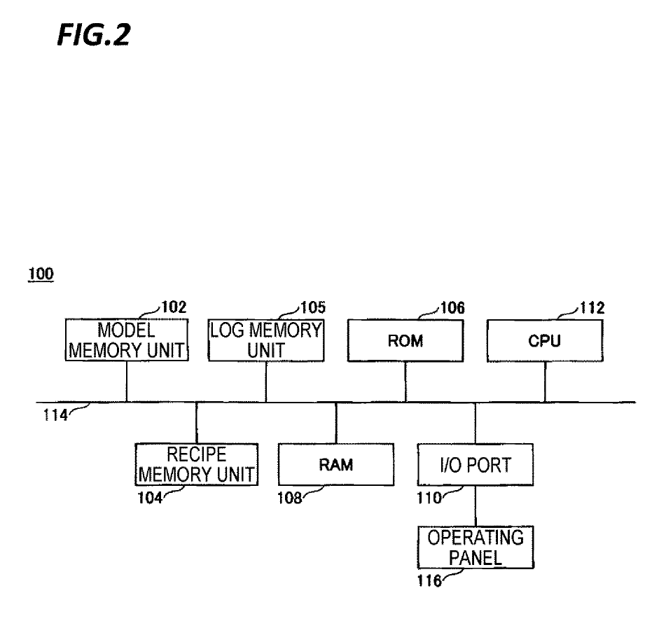

The control device 100 of the present exemplary embodiment will be described based on FIG. 2. FIG. 2 is a schematic view illustrating an exemplary configuration of the control device of the present exemplary embodiment.

As illustrated in FIG. 2, the control device 100 includes a model memory unit 102, a recipe memory unit 104, a log memory unit 105, a read only memory (ROM) 106, a random access memory (RAM) 108, an I/O port 110, a central processing unit (CPU) 112, and a bus 114 that interconnects the aforementioned components.

The model memory unit 102 stores, for example, a process model and a thermal model.

The process model refers to a model that represents the effect of the film formation condition on the film formation result, and may include, for example, a temperature-film thickness model and a number of cycles-film thickness model. The temperature-film thickness model refers to a model that represents the effect of the temperature of the wafer W on the film thickness of a formed film. The number of cycles-film thickness model refers to a model that represents the effect of the number of cycles of ALD on the film thickness of a formed film.

In addition, another process model may be a model that represents the effect of a film formation condition, such as the temperature of the wafer W, the number of cycles of ALD, the flow rate of a film formation gas, the supply time of the film formation gas, the pressure in the processing container 4, the supply time of a purge gas, or the number of revolutions per minute (rotational speed) of the wafer boat 48, on properties, such as the film thickness of a formed film, the density of impurities, sheet resistance, and reflectivity, or in-plane uniformity or inter-plane uniformity of these properties.

In addition, the model memory unit 102 may store some or all of the above-described process models.

In addition to the above-described process models, the model memory unit 102 stores a thermal model.

The thermal model refers to a model that represents a relationship between the temperature of the wafer W and the set temperature of the heater 60. The thermal model is referred when determining the set temperature of the heater 60 so that the temperature of the wafer W becomes the temperature of the wafer W calculated by the process model, such as, for example, the temperature-film thickness model.

In addition, in these models, it is considered that there may be a case where a default (predetermined) value is not optimum depending on the film formation condition or the state of the substrate processing apparatus. Thus, the learning of the models may be performed by incorporating a learning function to the models by adding, for example, an extended Kalman filter to software.

The recipe memory unit 104 stores a process recipe, which determines a control sequence according to the type of a film formation processing that is performed in the substrate processing apparatus. The process recipe refers to a recipe that is prepared for each film formation processing that an operator performs in practice. The process recipe defines film formation conditions, such as, for example, temperature variation, pressure variation, the initiation and stop timings of the supply of various gases, and the supply amount of various gases from the carry-in of wafers W to the substrate processing apparatus to the carry-out of completely processed wafers W.

The log memory unit 105 stores actual measurement values (hereinafter referred to as “log information”) of film formation conditions when a film is being formed on the wafer W. The log information may include actual measurement values of film formation conditions such as, for example, the temperature of the heater 60, the power of the heater 60, the flow rate of the film formation gas, the supply time of the film formation gas, the pressure in the processing container 4, the supply time of the purge gas, and the number of revolutions per minute of the wafer boat 48, for each predetermined time during the formation of a film (from the beginning to the end of a film formation processing).

The ROM 106 is configured by, for example, an electrically erasable programmable ROM (EEPROM), a flash memory, or a hard disc, and is a storage medium that stores, for example, an operating program of the CPU 112.

The RAM 108 functions as, for example, a work area of the CPU 112.

The I/O port 110 supplies a measured signal related to the film formation conditions, such as, for example, a temperature, a pressure, and a gas flow rate, to the CPU 112. In addition, the I/O port 110 outputs a control signal output from the CPU 112 to each component (e.g. a power controller 62, a controller (not illustrated) of the opening variable valve 34, or the flow rate adjustment unit 24). In addition, the I/O port 110 is connected to an operating panel 116, using which the operator operates the substrate processing apparatus.

The CPU 112 executes an operating program stored in the ROM 106, and controls an operation of the substrate processing apparatus based on the process recipe stored in the recipe memory unit 104 in response to an instruction from the operating panel 116.

In addition, the CPU 112 calculates the film formation condition that satisfies a target film property based on the measured result of the property of a film formed by the process recipe stored in the recipe memory unit 104, the process model stored in the model memory unit 102, and the log information stored in the log memory unit 105. At this time, the CPU 112 calculates the film formation condition that satisfies the in-plane uniformity of the wafer W and the inter-plane uniformity of the wafer W based on, for example, a predetermined film thickness and film quality stored in the process recipe, which is read using an optimization algorithm, such as, for example, linear programming or quadratic programming.

In addition, the CPU 112 set the temperature of the heater 60 to the temperature of the wafer W calculated by the process model based on the thermal model, which is stored in the model memory unit 102.

The bus 114 transmits information between the respective components.

When a film having a predetermined property is formed on the wafer W by ALD, theoretically, it is possible to form a uniform film on the wafer W. For example, when a sufficient amount of film formation gas is supplied to the wafer W, a sufficient amount of energy is supplied to activate the film formation gas, and a sufficient amount of film formation gas remaining in the processing container 4 is exhausted after a reaction, a uniform film may be formed on the wafer W.

However, the environments, such as, for example, the supply amount of film formation gas required to form the uniform film on the wafer W, the energy required to activate the film formation gas, and the time required to exhaust a sufficient amount of film formation gas remaining in the processing container 4 after a reaction, vary for each film formation condition. Therefore, in order to allow all assumed film formation conditions to satisfy the above environments, a large amount of time is required to calculate an optimum film formation condition, which increases manufacturing costs and deteriorates productivity. In addition, when a film having a predetermined property is formed on the wafer W by ALD, calculation of an optimum film formation condition is not easy because the optimum film formation condition is calculated by adjusting a plurality of parameters (e.g., temperature, gas flow rate, pressure, and number of cycles).

Accordingly, in the present exemplary embodiment, the film formation condition is calculated to satisfy a target film property based on the measured result of the property of the film formed by the process recipe stored in the recipe memory unit 104, the process model stored in the model memory unit 102, and the log information stored in the log memory unit 105. Thereby, the operator may easily calculate an optimum film formation condition under which a film is formed on the wafer W by ALD even if the operator has little knowledge or experience related to a semiconductor manufacturing apparatus or a semiconductor process. In addition, the time required to calculate the optimum film formation condition may be reduced.

Next, descriptions will be made on an operation (adjustment processing) of the control device, by which the operator may easily calculate an optimum film formation condition under which a film is formed on the wafer W by ALD even if the operator has little knowledge or experience related to a semiconductor manufacturing apparatus or a semiconductor process.

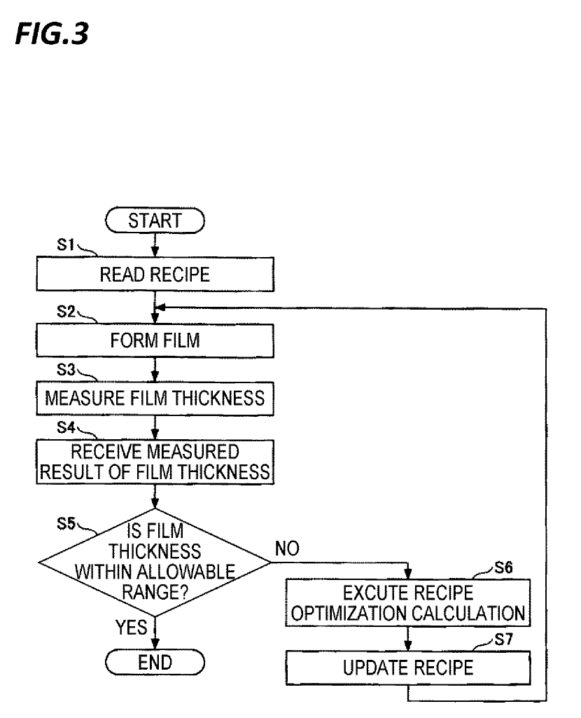

Hereinafter, descriptions will be made with reference to a where a SiN film is formed on the wafer W by ALD based on FIG. 3, by way of example. FIG. 3 is a flowchart illustrating an exemplary operation of the control device of the present exemplary embodiment.

The adjustment processing of the present exemplary embodiment may be performed in a setup step before a film formation processing is performed, or may be performed simultaneously with the film formation processing. In addition, in the adjustment processing, the operator may operate the operating panel 116 to select the type of a process (e.g. the film formation of a SiN film using DCS gas and NH₃ gas) and to input the film thickness (target film thickness) of the SiN film to be formed for each zone.

When required information, such as, for example, the process type, is input and a start command is received, the CPU 112 reads the process recipe corresponding to the input process type from the recipe memory unit 104 (step S1).

Subsequently, a SiN film is formed on the wafer W (step S2: a film formation process). Specifically, the CPU 112 moves down the cover 42, and disposes the wafer boat 48 having the wafers W mounted at least in the respective zones on the cover 42. Subsequently, the CPU 112 moves up the cover 42 to carry the wafer boat 48 into the processing container 4. Subsequently, the CPU 112 controls, for example, the flow rate adjustment unit 24, the opening variable valve 34, and the power controller 62 based on the process recipe read from the recipe memory unit 104, so as to form a SiN film on the wafer W. The SiN film is formed by alternately repeating an adsorption step of supplying DCS gas so that the DCS gas is adsorbed on the wafer W, and a reaction step of supplying NH₃ gas to react the DCS gas adsorbed on the wafer W with the NH₃ gas by a predetermined number of cycles.

When the formation of the SiN film is terminated, the CPU 112 moves down the cover 42 to carry out the wafer W having the SiN film formed thereon. A host computer transports the carried-out wafer W to a measurement device such as, for example, a film thickness gauge (not illustrated), so as to measure the film thickness of the SiN film (step S3: a measurement process). When the film thickness of the SiN film is measured, the film thickness gauge transmits the measured film thickness to the CPU 112 via the host computer. In addition, the operator may input the film thickness measured by the film thickness gauge by operating the operating panel 116.

When the CPU 112 receives the measured film thickness of the SiN film (step S4), the CPU determines whether or not the film thickness of the SiN film is within an allowable range of the target film thickness (step S5). The term “within the allowable range” means that the film thickness is included within a predetermined allowable range from the input target film thickness, and refers to, for example, a case where the thickness is within±1% from the input target film thickness.

In the step S5, when it is determined that the film thickness of the SiN film is within the allowable range of the target film thickness, the CPU 112 terminates the adjustment processing. In the step S5, when it is determined that the film thickness of the SiN film is not the film thickness within the allowable range of the target film thickness, the CPU 112 executes recipe optimization calculation (step S6: a calculation process). In the recipe optimization calculation, the CPU calculates the temperature of the wafer W in each zone and the number of cycles of ALD, which become the target film thickness, based on the film thickness of the SiN film received in the step S4, the temperature-film thickness model and the number of cycles-film thickness model stored in the model memory unit 102, and the actual measurement value of the temperature of the heater 60 stored in the log memory unit 105. At that time, as described above, an optimization algorithm, such as, for example, linear programming or quadratic programming may be used according to the use purpose. In addition, the set temperature of the heater 60 is calculated to be the temperature of the wafer W calculated by, for example, the process model based on the thermal model stored in the model memory unit 102. In addition, the set temperature of the heater 60 is adjusted in such a manner that the power of the heater 60 is not saturated, based on, for example, the set temperature of the heater 60, which is stored in the recipe memory unit 104, and the actual measurement value of the temperature of the heater 60 and the actual measurement value of the power of the heater 60, which are stored in the log memory unit 105.

Subsequently, the CPU 112 updates the set temperature of the heater 60 and the number of cycles of ALD of the read process recipe to the set temperature of the heater 60 and the number of cycles of ALD calculated in the step S6 (step S7), and returns to the step S2. The upstate of the process recipe may be overwriting of an existing process recipe, or may be writing of a new process recipe, separately from the existing process recipe.

### EXAMPLE

Hereinafter, although the present disclosure will be specifically described with reference to an example, the present disclosure is not construed as being limited to the example.

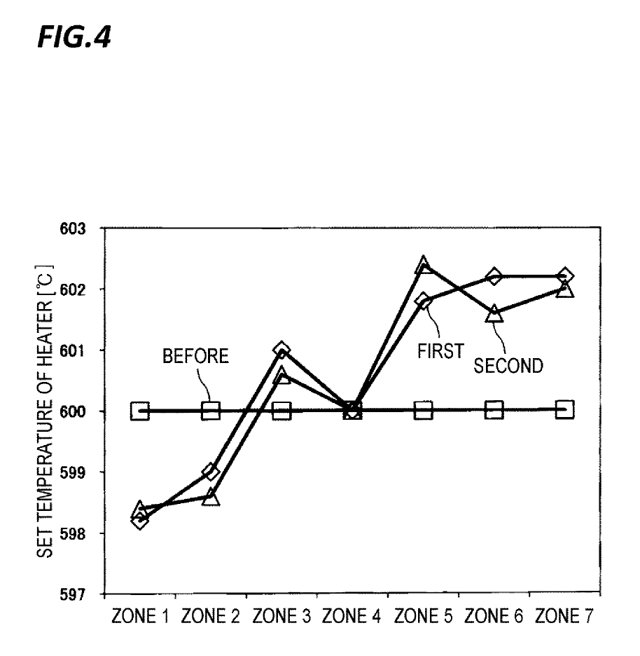

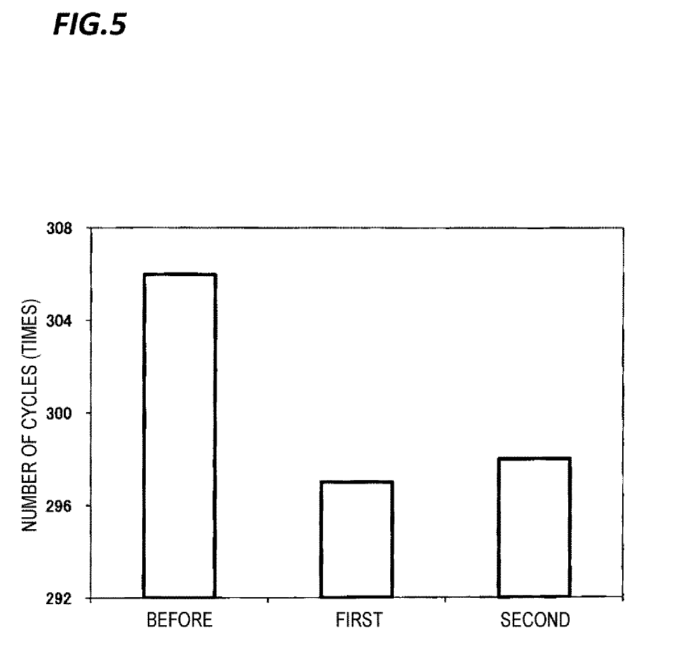

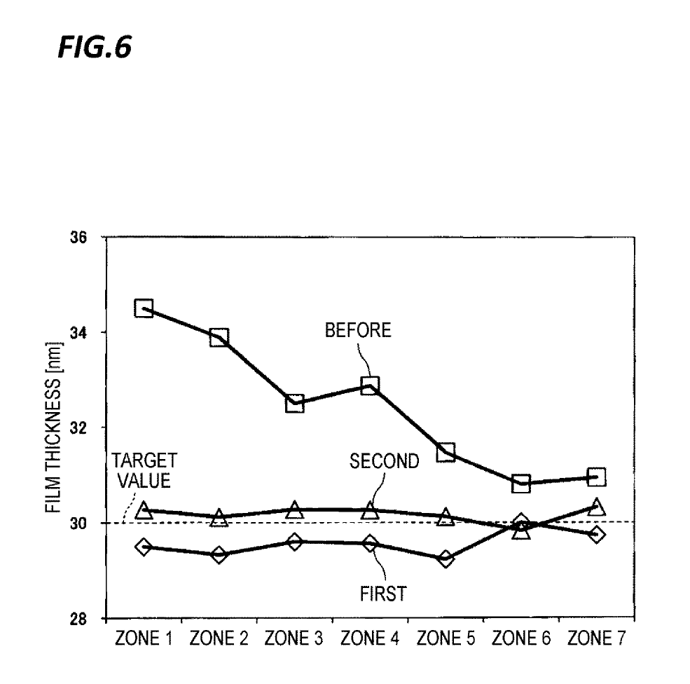

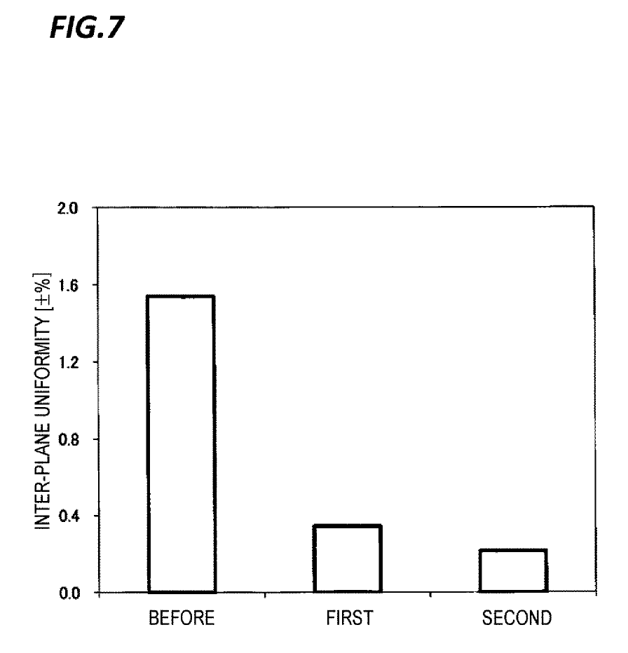

FIG. 4 is a view illustrating set temperature of the heater in respective zones before and after an adjustment processing, the horizontal axis represents the zones, and the vertical axis represents set temperature (° C.) of the heater. FIG. 5 is a view illustrating the numbers of cycles of ALD before and after an adjustment processing. FIG. 6 is a view illustrating a film thickness of a SiN film in each zone before and after an adjustment processing, the horizontal axis represents the zones, and the vertical axis represents the film thickness (nm). FIG. 7 is a view illustrating inter-plane uniformity (±%) in film thickness of a SiN film in each zone before and after an adjustment processing. In addition, in FIGS. 4 to 7, a set value and an actual measurement value before the adjustment processing are indicated by “before,” a set value and an actual measurement value after a first adjustment processing are indicated by “first”, and a set value and an actual measurement value after a second adjustment processing are indicated by “second”.

First, as illustrated in FIGS. 4 and 5, a SiN film was formed on the wafer W under the condition in which the set temperature of the heaters 60a to 60g was 600° C. and the number of cycles of ALD was 306 times (see “before” in FIGS. 4 and 5), and the film thickness of the formed SiN film was measured. In addition, the target film thickness, the film formation gas, the process model, and the log information are as follows.

(Film Formation Condition)

Target film thickness: 30.0 nm

Film formation gas: DCS gas (2 slm, 25 seconds/cycle), NH₃ gas (20 slm, 35 seconds/cycle)

Process model: temperature-film thickness model, the number of cycles-film thickness model

Log information: the actual measurement value of the temperature of the heater 60, the actual measurement value of the power of the heater 60

As illustrated in FIG. 6, the film thickness of the SiN film has value larger than a target value (30 nm) in all zones (zone 1 to zone 7). In addition, as illustrated in FIG. 7, the inter-plane uniformity in film thickness of the SiN film was about±1.5%.

Subsequently, the above-described adjustment processing (hereinafter, referred to as “first adjustment processing”) was performed using the measured result of the film thickness of the SiN film, and the set temperature of the heater 60 and the number of cycles of ALD were calculated. In addition, the SiN film was formed on the wafer W under the updated film formation condition (see “first” in FIGS. 4 and 5) of the calculated set temperature of the heater 60 and the calculated number of cycles of ALD, and the film thickness of the formed SiN film was measured.

As illustrated in FIG. 6, the film thickness of the SiN film formed after the first adjustment processing has a value closer to the target value than the film thickness of the SiN film formed before the adjustment processing. In addition, as illustrated in FIG. 7, the inter-plane uniformity of the film thickness of the SiN film formed after the first adjustment processing was improved compared to the inter-plane uniformity in film thickness of the SiN film before the adjustment processing, and was about±0.3%.

Subsequently, the above-described adjustment processing (hereinafter, referred to as “second adjustment processing”) was performed using the measured result of the film thickness of the SiN film after the first adjustment processing, and the set temperature of the heater 60 and the number of cycles of ALD were calculated. In addition, a SiN film was formed on the wafer W using the updated film formation condition (see “second” in FIGS. 4 and 5) of the set temperature of the heater 60 and the number of cycles of ALD, which were calculated by the second adjustment processing, and the film thickness of the formed SiN film was measured.

As illustrated in FIG. 6, the film thickness of the SiN film formed after the second adjustment processing was the value that is closer to the target value than the film thickness of the SiN film formed after the first adjustment processing. In addition, as illustrated in FIG. 7, the inter-plane uniformity of the film thickness of the SiN film formed after the second adjustment processing was improved compared to the inter-plane uniformity of the film thickness of the SiN film formed after the first adjustment processing, and was about±0.2%.

In this way, by performing the adjustment processing of the present exemplary embodiment, the optimum film formation condition was easily calculated. Specifically, in the example, by performing the adjustment processing two times, in all zones (zone 1 to zone 7), the film thickness that is substantially equal to the target film thickness was acquired.

As described above, in the present exemplary embodiment, the control device 100 calculates the film formation condition that satisfies a target film property based on the measured result of the property of a film formed by the process recipe stored in the recipe memory unit 104, the process model stored in the model memory unit 102, and the log information stored in the log memory unit 105. Thereby, an operator may easily calculate an optimum film formation condition under which a film is formed on the wafer W by atomic layer deposition even if the operator has little knowledge or experience related to a semiconductor manufacturing apparatus or a semiconductor process. In addition, the time required until the optimum film formation condition is calculated may be reduced.

Although the control device, the substrate processing system, the substrate processing method, and the program have been described above by the example, the present disclosure is not limited to the example, and various modifications and improvements are possible within the scope of the present disclosure.

Although the present exemplary embodiment has been described with reference to a form of adjusting the set temperature of the heater 60 and the number of cycles of ALD by recipe optimization calculation, the present disclosure is not limited thereto. For example, any one of the set temperature of the heater 60 and the number of cycles of ALD may be adjusted. In addition, one film formation condition selected from other film formation conditions, for example, the flow rate of the film formation gas, the supply time of the film formation gas, the pressure in the processing container 4, the supply time of the purge gas, and the number of revolutions per minute (rotational speed) of the wafer boat 48 may be adjusted. In addition, a plurality of film formation conditions selected from these film formation conditions may be adjusted at the same time.

In addition, although the present exemplary embodiment has been described with reference to a batch type apparatus in which a plurality of wafers W disposed in the wafer boat 48 constitutes a single batch and a film formation processing is performed on each batch by way of example, the present disclosure is not limited thereto. For example, the present disclosure may be applied to a semi-batch type apparatus in which a film formation processing is performed on a plurality of wafers W disposed on a holder, or a sheet type apparatus in which a film formation processing is performed on each wafer.

In addition, although the present embodiment has been described with reference to a case where the control device 100 that controls an operation of the substrate processing apparatus, performs the adjustment processing by way of example, the present disclosure is not limited thereto. For example, a control device (group controller) or a host computer that collectively manages a plurality of devices may perform the adjustment processing.

In addition, although the present embodiment has been described with reference to a film thickness of the formed film as a control target by way of example, the present disclosure is not limited thereto. The control target may be properties, such as, for example, the density of impurities, the sheet resistance, and the reflectivity of the formed film.

From the foregoing, it will be appreciated that various exemplary embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A control device that controls an operation of a substrate processing apparatus that forms a film on a substrate by atomic layer deposition, the control device comprising:
a recipe memory unit configured to store a film formation condition according to a type of the film;
a model memory unit configured to store a process model that represents an effect of the film formation condition on a property of the film;
a log memory unit configured to store an actual measurement value of the film formation condition during film formation; and
a controller configured to calculate a film formation condition that satisfies a target property of the film based on a measured result of the property of the film formed based on the film formation condition stored in the recipe memory unit, the process model stored in the model memory unit, and the actual measurement value of the film formation condition stored in the log memory unit.

2. The control device according to claim 1, wherein the film formation condition includes a temperature of the substrate,
the model memory unit further stores a thermal model that represents a relationship between the temperature of the substrate and a set temperature of a heater that heats the substrate, and
the controller determines the set temperature of the heater based on the thermal model stored in the model memory unit so that the temperature of the substrate becomes a temperature calculated by the process model.

3. The control device according to claim 2, wherein the controller adjusts the film formation condition based on the actual measurement value of the film formation condition stored in the log memory unit such that power of the heater is not saturated.

4. The control device according to claim 1, wherein the controller calculates the film formation condition that satisfies the target property of the film using an optimization algorithm.

5. The control device according to claim 1, wherein the property of the film is a film thickness.

6. A substrate processing system comprising:
a substrate processing apparatus that form a film on a substrate by atomic layer deposition; and
a control device configured to control an operation of the substrate processing apparatus,
wherein the control device includes:
a recipe memory unit configured to store a film formation condition according to a type of the film;
a model memory unit configured to store a process model that represents an effect of the film formation condition on a property of the film;
a log memory unit configured to store an actual measurement value of the film formation condition during film formation; and
a controller configured to calculate a film formation condition that satisfies a target property of the film based on a measured result of the property of the film formed based on the film formation condition stored in the recipe memory unit, the process model stored in the model memory unit, and the actual measurement value of the film formation condition stored in the log memory unit.

7. The substrate processing system according to claim 6, wherein the substrate processing apparatus includes:
a substrate holding mechanism configured to hold a plurality of substrates at predetermined intervals in a vertical direction;
a processing container configured to accommodate the substrate holding mechanism therein; and
a gas supply unit configured to supply a first processing gas and a second processing gas, which reacts with the first processing gas, into the processing container.

8. The substrate processing system according to claim 7, wherein the first processing gas is dichlorosilane gas, and the second processing gas is ammonia gas.

9. A substrate processing method comprising:
forming a film on a substrate using a predetermined film formation condition by atomic layer deposition;
measuring a property of the film formed in the film formation process; and
calculating a film formation condition that satisfies a target property of the film based on a measured result of the property of the film formed based on a measured result of the property of the film measured in the measurement process, a process model that represents an effect of the film formation condition on the property of the film, and an actual measurement value of the film formation condition during film formation.

10. A non-transitory computer-readable storage medium storing a program that, when executed, causes a computer to perform the substrate processing method of claim 9.
